(19) United States
(12) Patent Application Publication
(10) Pub. No.: US 2025/0183169 A1
(43) Pub. Date: Jun. 5, 2025

(54) SEMICONDUCTOR PACKAGE

(71) Applicant: Samsung Electronics Co., Ltd., Suwon-si (KR)

(72) Inventors: Won Il Lee, Suwon-si (KR); Hyungchul Shin, Suwon-si (KR); Enbin Jo, Suwon-si (KR)

(21) Appl. No.: 18/762,892

(22) Filed: Jul. 3, 2024

(30) Foreign Application Priority Data
Dec. 1, 2023 (KR) 10-2023-0172685

(51) Int. Cl. H01L 23/528; H01L 23/00; H01L 23/522; H01L 23/532; H01L 25/18

(52) U.S. Cl. CPC H01L 23/5283; H01L 23/5226; H01L 23/5329; H01L 23/562; H01L 24/06; H01L 24/08; H01L 24/80; H01L 25/18; H01L 2224/0603; H01L 2224/08146; H01L 2224/80895; H01L 2224/80896; H01L 2225/06544; H01L 2924/1431

(57) ABSTRACT

Provided is a semiconductor package including stacked semiconductor chips. Respective ones of the semiconductor chips include a substrate having front and rear surfaces, an interlayer dielectric layer on the front surface of the substrate, a lower protection layer on a bottom surface of the interlayer dielectric layer, lower conductive pads in the lower protection layer, an upper protection layer on the rear surface of the substrate, and upper conductive pads in the upper protection layer. The upper conductive pads of a first one of the semiconductor chips are respectively in contact with the lower conductive pads of an adjacent one of the semiconductor chips. Each of the upper protection layer and the lower protection layer has a non-uniform thickness. Ones of the lower conductive pads have respective thicknesses that are different from each other.

### CROSS-REFERENCE TO RELATED APPLICATIONS

This U.S. nonprovisional application claims priority under 35 U.S.C. § 119 to Korean Patent Application No. 10-2023-0172685 filed on Dec. 1, 2023 in the Korean Intellectual Property Office, the disclosure of which is hereby incorporated by reference in its entirety.

### BACKGROUND OF THE INVENTION

The present inventive concepts relate to a semiconductor package.

A semiconductor package is provided to implement an integrated circuit chip to qualify for use in electronic products. A semiconductor package is typically configured such that a semiconductor chip is mounted on a printed circuit board (PCB) and bonding wires or bumps are used to electrically connect the semiconductor chip to the printed circuit board. With the development of the electronics industry, various studies have been conducted to improve reliability and durability of semiconductor packages.

### SUMMARY OF THE INVENTION

Example embodiments of the present inventive concepts provide a semiconductor package with increased durability and improved structural stability.

The object of the present inventive concepts is not limited to that mentioned above, and other objects which have not been mentioned above will be clearly understood to those skilled in the art from the following description. According to some embodiments of the present inventive concepts, a semiconductor package may include a plurality of semiconductor chips that are sequentially stacked. Respective ones of the semiconductor chips may include a substrate that has a front surface and a rear surface, an interlayer dielectric layer on the front surface of the substrate, a lower protection layer on a bottom surface of the interlayer dielectric layer, a plurality of lower conductive pads in the lower protection layer, an upper protection layer on the rear surface of the substrate, and a plurality of upper conductive pads in the upper protection layer. The upper conductive pads of a first one of the respective ones of the semiconductor chips may respectively be in contact with the lower conductive pads of an adjacent one of the respective ones of the semiconductor chips. Each of the upper protection layer and the lower protection layer may have a non-uniform thickness. Ones of the lower conductive pads may have respective thicknesses that are different from each other.

According to some embodiments of the present inventive concepts, a semiconductor package may include a first semiconductor chip, and second to fifth semiconductor chips that are sequentially stacked on the first semiconductor chip. The first semiconductor chip may include a first substrate that has a first front surface and a first rear surface opposite to each other, a first interlayer dielectric layer on the first front surface of the first substrate, a plurality of first lower protection layers that are stacked below the first interlayer dielectric layer, a plurality of first lower conductive pads in a lowermost one of the first lower protection layers, a plurality of first upper protection layers that are stacked on the first rear surface of the first substrate, and a plurality of first upper conductive pads in an uppermost one of the first upper protection layers. Respective ones of the second to fifth semiconductor chips may include a second substrate that has a second front surface and a second rear surface opposite to each other, a second interlayer dielectric layer on the second front surface of the second substrate, a plurality of second lower protection layers that are stacked below the second interlayer dielectric layer, a plurality of second lower conductive pads in a lowermost one of the second lower protection layers, a plurality of second upper protection layers that are stacked on the second rear surface of the second substrate, and a plurality of second upper conductive pads in an uppermost one of the second upper protection layers. The second upper conductive pads of a first one of the respective ones of the second to fifth semiconductor chips may respectively be in contact with the second lower conductive pads of an adjacent one of the respective ones of the second to fifth semiconductor chips. The second upper conductive pads may include a same material as the second lower conductive pads. The uppermost one of the second upper protection layers may have a non-uniform thickness. The lowermost one of the second lower protection layers may have a non-uniform thickness. A first interface between the uppermost one of the second upper protection layers and an underlying one of the second upper protection layers may be curved. A second interface between the lowermost one of the second lower protection layers and an overlying one of the second lower protection layers may be curved.

According to some embodiments of the present inventive concepts, a semiconductor package may include a package substrate, an interposer substrate on the package substrate, a plurality of first chip structures on the interposer substrate, and a second chip structure on the interposer substrate. Each of the plurality of first chip structures may include a plurality of semiconductor chips that are sequentially stacked. Respective ones of the semiconductor chips may include a substrate that has a front surface and a rear surface, an interlayer dielectric layer on the front surface of the substrate, a lower protection layer on a bottom surface of the interlayer dielectric layer, a plurality of lower conductive pads in the lower protection layer, an upper protection layer on the rear surface of the substrate, and a plurality of upper conductive pads in the upper protection layer. The upper conductive pads of a first one of the respective ones of the semiconductor chips may respectively be in contact with the lower conductive pads of an adjacent one of the respective ones of the semiconductor chips. Each of the upper protection layer and the lower protection layer may have a non-uniform thicknesses. The non-uniform thickness of each of the upper protection layer and the lower protection layer may be in a range of about 100 angstroms (Å) to about 5,000 Å.

### BRIEF DESCRIPTION OF THE DRAWINGS

FIG. 1 illustrates a cross-sectional view showing a semiconductor package according to some embodiments of the present inventive concepts.

FIGS. 2A and 2B illustrate enlarged views showing section P1 of FIG. 1.

FIGS. 3A to 3J illustrate cross-sectional views showing a method of fabricating a semiconductor package depicted in FIG. 1 according to some embodiments of the present inventive concepts.

FIGS. 4A and 4B illustrate partially enlarged views showing section P2 of FIG. 3E.

FIGS. 5A and 5B illustrate partially enlarged views showing section P3 of FIG. 3F.

FIG. 6A illustrates a cross-sectional view showing a semiconductor package according to some embodiments of the present inventive concepts.

FIG. 6B illustrates an enlarged view showing section P4 of FIG. 6A.

FIG. 7 illustrates a cross-sectional view showing a semiconductor package according to some embodiments of the present inventive concepts.

### DETAILED DESCRIPTION

Example embodiments of the present inventive concepts will now be described in detail with reference to the accompanying drawings to aid in clearly explaining the present inventive concepts.

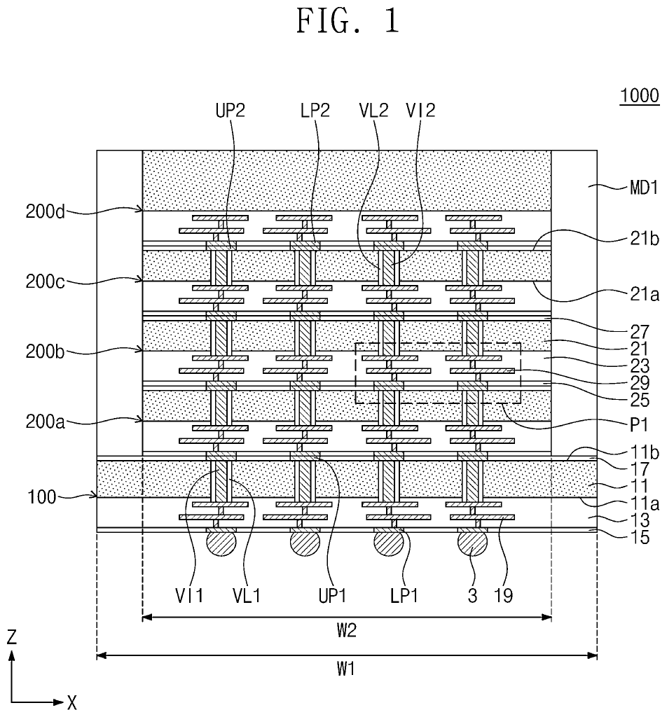

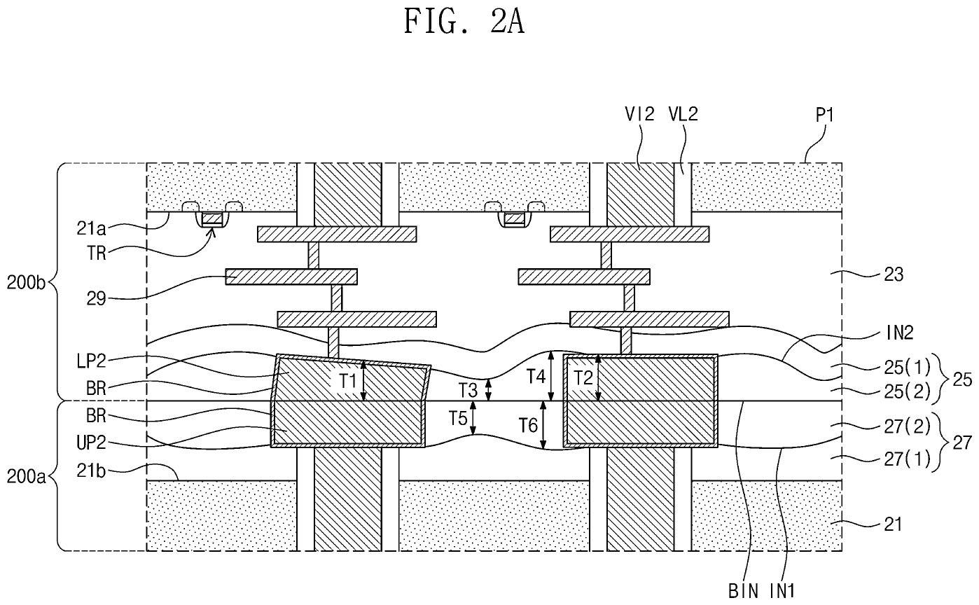

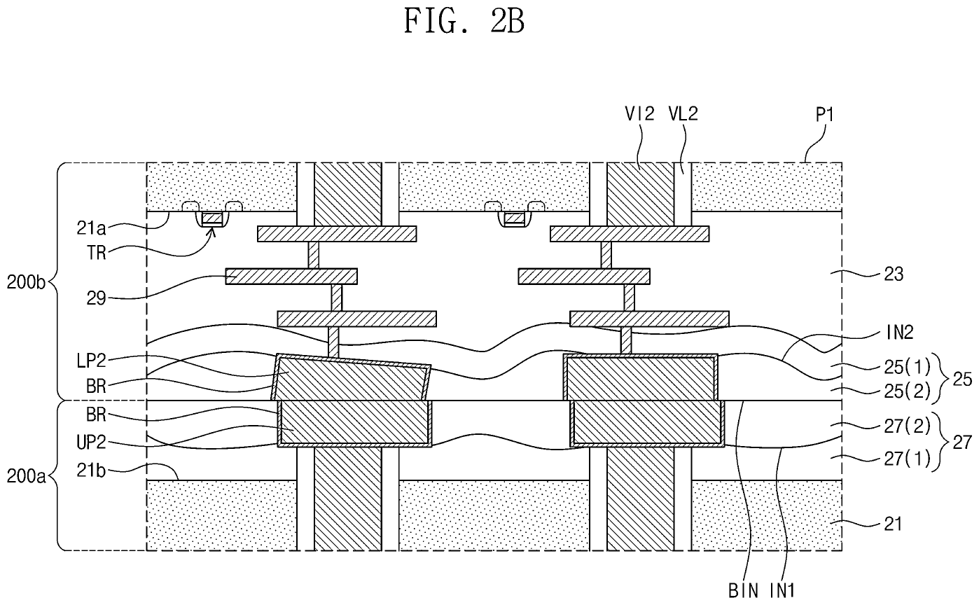

FIG. 1 illustrates a cross-sectional view showing a semiconductor package according to some embodiments of the present inventive concepts. FIGS. 2A and 2B illustrate enlarged views showing section P1 of FIG. 1.

Referring to FIG. 1, a semiconductor package 1000 according to some embodiments may include a first semiconductor chip 100, second to fifth semiconductor chips 200a, 200b, 200c, and 200d that are sequentially stacked on the first semiconductor chip 100, and a first mold layer MD1 that is on (e.g., that covers) the first to fifth semiconductor chips 100 and 200a to 200d. The term “semiconductor chip” may also be called a die.

The first semiconductor chip 100 may be, for example, a logic circuit chip. The first semiconductor chip 100 may serve as an interface circuit between an external controller and the second to fifth semiconductor chips 200a to 200d. The first semiconductor chip 100 may receive commands, data, and signals transmitted from the external controller, and may transfer the received commands, data, and signals to the second to fifth semiconductor chips 200a to 200d. In other embodiments, the first semiconductor chip 100 may be a memory chip, such as a Flash memory chip, a dynamic random access memory (DRAM) chip, a static random access memory (SRAM) chip, an electrically erasable programmable read-only memory (EEPROM) chip, a phase change random access memory (PRAM) chip, a magnetic random access memory (MRAM) chip, or a resistive random access memory (ReRAM) chip. In another embodiment, the first semiconductor chip 100 may be an interposer die including no transistor.

The second to fifth semiconductor chips 200a to 200d may be chips of different types from the first semiconductor chip 100. In some embodiments, the second to fifth semiconductor chips 200a to 200d may be the same memory chip. For example, each of the second to fifth semiconductor chips 200a to 200d may be a Flash memory chip, a dynamic random access memory (DRAM) chip, a static random access memory (SRAM) chip, an electrically erasable programmable read-only memory (EEPROM) chip, a phase change random access memory (PRAM) chip, a magnetic random access memory (MRAM) chip, or a resistive random access memory (ReRAM) chip. The first semiconductor chip 100 may have a first width W1 that is greater than a second width W2 of each of the second to fifth semiconductor chips 200a to 200d.

FIG. 1 illustrates a structure in which, for example, one logic circuit chip and four memory chips are stacked, but the number of stacked logic circuit and memory chips may be variously changed without being limited thereto. For example, eight, twelve, or more memory chips may be stacked. In some embodiments, the semiconductor package 1000 may have a high bandwidth memory (HBM) chip structure. In other embodiments, the semiconductor package 1000 may have a bonding structure such as a die-to-die bonding, a die-to-wafer bonding, or a wafer-on-wafer bonding.

The first semiconductor chip 100 may include a first substrate 11, a first through via VI1, first wiring lines 19, a first interlayer dielectric layer 13, first upper conductive pads UP1, first lower conductive pads LP1, a first upper protection layer 17, and a first lower protection layer 15.

The first substrate 11 may have a first front surface 11a and a first rear surface 11b that are opposite to each other. Although not shown, transistors may be disposed on the first front surface 11a of the first substrate 11. The transistors (not shown) and the first wiring lines 19 to be described later may constitute integrated circuits. The first substrate 11 may be a semiconductor substrate formed of a semiconductor material such as silicon, a silicon-on-insulator (SOI) substrate, or a dielectric substrate.

The first through via VI1 may extend into (e.g., may penetrate) the first substrate 11. A first through dielectric layer VL1 may be interposed between the first through via VI1 and the first substrate 11. The first through via VI1 may include metal, such as copper, aluminum, or tungsten. The first through dielectric layer VL1 may have a single-layered or multi-layered structure of at least one selected from silicon oxide, silicon nitride, and silicon oxynitride. The first through dielectric layer VL1 may include an air gap.

The first wiring lines 19 may be disposed on the first front surface 11a of the first substrate 11. The first wiring lines 19 may be formed of multi-layered wiring patterns. The first wiring lines 19 may be electrically connected to the first through via VI1. The first wiring lines 19 may include metal, such as copper, aluminum, gold, nickel, or titanium.

The first interlayer dielectric layer 13 may be on (e.g., may cover) the first wiring lines 19 and the first front surface 11a of the first substrate 11. The first interlayer dielectric layer 13 may have a single-layered or multi-layered structure of at least one selected from silicon oxide, silicon nitride, silicon oxynitride, and porous dielectrics.

The first upper conductive pads UP1 may be disposed on the first rear surface 11b of the first substrate 11. The first upper conductive pads UP1 may be electrically connected to integrated circuits of the first semiconductor chip 100, while being in contact with corresponding first through vias VI1. Although not shown, the first upper conductive pads UP1 of the first semiconductor chip 100 may have their thickness that are different from each other depending on position. In other words, ones of the first upper conductive pads UP1 may have thicknesses that are different from each other. The first lower conductive pads LP1 may be disposed on a bottom surface of the first interlayer dielectric layer 13. The first lower conductive pads LP1 may be electrically connected to integrated circuits of the first semiconductor chip 100. The phrase “components are electrically connected to each other” (or similar language) may include a direct connection or an indirect connection through other component(s). The first upper conductive pads UP1 and the first lower conductive pads LP1 may include metal, such as copper, gold, nickel, aluminum, or tungsten.

The first upper protection layer 17 may be on (e.g., may cover) the first rear surface 11b of the first substrate 11. The first upper conductive pads UP1 may be disposed in the first upper protection layer 17. For example, the first upper protection layer 17 may be on (e.g., may cover) lateral surfaces of the first upper conductive pads UP1. The first lower protection layer 15 may be on (e.g., may cover) the bottom surface of the first interlayer dielectric layer 13. The first lower conductive pads LP1 may be disposed in the first lower protection layer 15. For example, the first lower protection layer 15 may be on (e.g., may cover) lateral surfaces of the first lower conductive pads LP1. Each of the first upper protection layer 17 and the first lower protection layer 15 may have a structure in which a plurality of layers are stacked. For example, the first lower conductive pads LP1 may be in a lowermost one of the plurality of layers of the first lower protection layer 15, and the first upper conductive pads UP1 may be in an uppermost one of the plurality of layers of the first upper protection layer 17. Each of the first upper protection layer 17 and the first lower protection layer 15 may have, for example, a single-layered or multi-layered structure of at least one selected from silicon oxide, silicon nitride, and silicon carbonitride. In some embodiments, a lowermost one of the plurality of layers of the first lower protection layer 15 and an uppermost one of the plurality of layers of the first upper protection layer 17 may each have a thickness in a range of about 100 angstroms (Å) to about 5,000 Å.

First connection terminals 3 may be bonded to the first lower conductive pads LP1 of the first semiconductor chip 100. The first connection terminals 3 may include at least one selected from conductive bumps and solder balls. The first connection terminals 3 may include, for example, at least one selected from copper, nickel, tin, lead, silver, and any alloy thereof.

Referring to FIGS. 1, 2A, and 2B, each of the second, third, fourth, and fifth semiconductor chips 200a, 200b, 200c, and 200d may include a second substrate 21, a second through via VI2, second wiring lines 29, a second interlayer dielectric layer 23, second upper conductive pads UP2, second lower conductive pads LP2, a second upper protection layer 27, and a second lower protection layer 25.

The second substrate 21 may have a second front surface 21a and a second rear surface 21b that are opposite to each other. Transistors TR may be disposed on the second front surface 21a of the second substrate 21. The transistors TR and the second wiring lines 29 to be described later may constitute integrated circuits. The second substrate 21 may be a semiconductor substrate formed of a semiconductor material such as silicon, a silicon-on-insulator (SOI) substrate, or a dielectric substrate.

The second through via VI2 may extend into (e.g., may penetrate) the second substrate 21. A second through dielectric layer VL2 may be interposed between the second through via VI2 and the second substrate 21. The second through via VI2 may include metal, such as copper, aluminum, or tungsten. The second through dielectric layer VL2 may have a single-layered or multi-layered structure of at least one selected from silicon oxide, silicon nitride, and silicon oxynitride. The second through dielectric layer VL2 may include an air gap.

The second wiring lines 29 may be disposed on the second front surface 21a of the second substrate 21. The second wiring lines 29 may be formed of multi-layered wiring patterns. The second wiring lines 29 may be electrically connected to the second through via VI2. The second wiring lines 29 may include metal, such as copper, aluminum, gold, nickel, or titanium.

The second interlayer dielectric layer 23 may be on (e.g., may cover) the second wiring lines 29 and the second front surface 21a of the second substrate 21. The second interlayer dielectric layer 23 may have a single-layered or multi-layered structure of at least one selected from silicon oxide, silicon nitride, silicon oxynitride, and porous dielectrics.

The second upper conductive pads UP2 may be disposed on the second rear surface 21b of the second substrate 21. The second upper conductive pads UP2 may be electrically connected to integrated circuits of the second to fifth semiconductor chips 200a to 200d, while being in contact with corresponding second through vias VI2. The second lower conductive pads LP2 may be disposed on a bottom surface of the second interlayer dielectric layer 23. The second lower conductive pads LP2 may be electrically connected to integrated circuits of the second to fifth semiconductor chips 200a to 200d. The phrase “components are electrically connected to each other” (or similar language) may include a direct connection or an indirect connection through other component(s). The second upper conductive pads UP2 and the second lower conductive pads LP2 may each include metal, such as copper, gold, nickel, aluminum, or tungsten.

The second upper protection layer 27 may be on (e.g., may cover) the second rear surface 21b of the second substrate 21. The second upper conductive pads UP2 may be disposed in the second upper protection layer 27. For example, the second upper protection layer 27 may be on (e.g., may cover) lateral surfaces of the second upper conductive pads UP2. The second lower protection layer 25 may be on (e.g., may cover) the bottom surface of the second interlayer dielectric layer 23. The second lower conductive pads LP2 may be disposed in the second lower protection layer 25. For example, the second lower protection layer 25 may be on (e.g., may cover) lateral surfaces of the second lower conductive pads LP2. Each of the second upper protection layer 27 and the second lower protection layer 25 may have a structure in which a plurality of layers are stacked. Each of the second upper protection layer 27 and the second lower protection layer 25 may have, for example, a single-layered or multi-layered structure of at least one selected from silicon oxide, silicon nitride, and silicon carbonitride.

A barrier layer BR may be interposed between the second upper protection layer 27 and the second upper conductive pads UP2 and between the second lower protection layer 25 and the second lower conductive pads LP2. The barrier layer BR may include at least one or two selected from titanium, tantalum, titanium nitride, tantalum nitride, and tungsten nitride. The barrier layer BR may be considered to be a part of the second upper conductive pad UP2 and/or the second lower conductive pad LP2. The second upper conductive pad UP2 may be in contact with the second through via VI2. For example, the barrier layer BR included in the second upper conductive pad UP2 may be in contact with the second through via VI2.

The first mold layer MD1 may be on (e.g., may cover) a top surface of the first semiconductor chip 100 and lateral surfaces of the second to fifth semiconductor chips 200a to 200d. The first mold layer MD1 may include a dielectric resin, such as an epoxy molding compound (EMC). The first mold layer MD1 may further include fillers, and the fillers may be dispersed in the dielectric resin. The fillers may include, for example, silicon oxide (SiO₂).

Referring to FIG. 2A, the second upper conductive pads UP2 of the second semiconductor chip 200a may respectively be in direct contact with the second lower conductive pads LP2 of the third semiconductor chip 200b. The second upper conductive pads UP2 of a lower one of adjacent ones of the second to fifth semiconductor chips 200a to 200d may respectively be in contact with the second lower conductive pads LP2 of an upper one of adjacent ones of the second to fifth semiconductor chips 200a to 200d. For example, the adjacent ones of the second to fifth semiconductor chips 200a to 200d may be adjacent to each other in a second direction Z (e.g., a vertical direction). The second direction Z may be substantially perpendicular to the first front surface 11a of the first substrate 11. The second upper conductive pads UP2 and the second lower conductive pads LP2 may include the same material. Among the second upper conductive pads UP2 and the second lower conductive pads LP2, contacted ones may be merged into a single unitary object. For example, each of the contacted ones of the second upper conductive pads UP2 and the second lower conductive pads LP2 may appear as a single monolithic structure. The second upper protection layer 27 of a lower one of adjacent ones of the second to fifth semiconductor chips 200a to 200d may be in contact with the second lower protection layer 25 of an upper one of adjacent ones of the second to fifth semiconductor chips 200a to 200d.

For example, the second lower conductive pads LP2 of the third semiconductor chip 200b may have a first thickness T1 and a second thickness T2 that are different from each other. The first thickness T1 and the second thickness T2 may be taken in the second direction Z (e.g., a vertical direction). Although FIG. 2A depicts the first thickness T1 and the second thickness T2, the present inventive concepts are not limited thereto and the second lower conductive pads LP2 may have different thicknesses depending on position. The second upper conductive pads UP2 and the second lower conductive pads LP2 of the second to fifth semiconductor chips 200a to 200d may have different thicknesses depending on position.

The second upper protection layer 27 of each of the second to fifth semiconductor chips 200a to 200d may include, for example, third and fourth upper protection layers 27(1) and 27(2) that are sequentially stacked as shown in FIG. 2A. The present inventive concepts, however, are not limited thereto, and the second upper protection layer 27 may be formed of three or more stacked protection layers. A first interface IN1 having a curved shape may be provided between the third upper protection layer 27(1) and the fourth upper protection layer 27(2). For example, a bottom surface of the fourth upper protection layer 27(2) may be curved. The first interface IN1 may not be exposed. The fourth upper protection layer 27(2) in an upper portion of the second upper protection layer 27 may have a thickness T5 or T6 in a range of about 100 angstroms (Å) to about 5,000 Å. The fourth upper protection layer 27(2) may have thicknesses T5 and T6 that are different depending on position. In other words, the fourth upper protection layer 27(2) may have a non-uniform thickness. A minimum thickness T5 of the fourth upper protection layer 27(2) may be in a range of about 0.1 times to about 0.9 times a maximum thickness T6 of the fourth upper protection layer 27(2).

The second lower protection layer 25 of each of the second to fifth semiconductor chips 200a to 200d may include third and fourth lower protection layers 25(1) and 25(2) that are sequentially stacked. The present inventive concepts, however, are not limited thereto, and the second lower protection layer 25 may be formed of three or more stacked protection layers. A second interface IN2 having a curved shape may be provided between the third lower protection layer 25(1) and the fourth lower protection layer 25(2). For example, a top surface of the fourth lower protection layer 25(2) may be curved. The second interface IN2 may not be exposed. The fourth lower protection layer 25(2) in a lower portion of the second lower protection layer 25 may have a thickness T3 or T4 in a range of about 100 Å to about 5,000 Å. The fourth lower protection layer 25(2) may have different thicknesses T3 and T4 that are different depending on position. In other words, the fourth lower protection layer 25(2) may have a non-uniform thickness. A minimum thickness T3 of the fourth lower protection layer 25(2) may be in a range of about 0.1 times to about 0.9 times a maximum thickness T4 of the fourth lower protection layer 25(2).

The fourth upper protection layer 27(2) of a lower one of adjacent ones of the second to fifth semiconductor chips 200a to 200d may be in contact with the fourth lower protection layer 25(2) of an upper one of adjacent ones of the second to fifth semiconductor chips 200a to 200d. A bonding interface BIN having a flat shape may be provided between the fourth upper protection layer 27(2) and the fourth lower protection layer 25(2) that are in contact with each other. As the bonding interface BIN is not curved but is instead flat, there may be a reduction in the occurrence of voids at the bonding interfaces BIN between the second to fifth semiconductor chips 200a to 200d. Accordingly, the semiconductor package 1000 may have improved durability and structural stability.

Referring back to FIG. 1, the first upper conductive pads UP1 of the first semiconductor chip 100 may respectively be in contact with the second lower conductive pads LP2 of the second semiconductor chip 200a. The first upper conductive pads UP1 of the first semiconductor chip 100 may include the same material as that of the second lower conductive pads LP2 of the second semiconductor chip 200a. Among the first upper conductive pads UP1 of the first semiconductor chip 100 and the second lower conductive pads LP2 of the second semiconductor chip 200a, ones in contact with each other may be merged into a single unitary object.

The first upper protection layer 17 of the first semiconductor chip 100 may be in contact with the second lower protection layer 25 of the second semiconductor chip 200a. A bonding interface having a flat shape may be provided between the first upper protection layer 17 of the first semiconductor chip 100 and the second lower protection layer 25 of the second semiconductor chip 200a. As the bonding interface is not curved but is instead flat, there may be a reduction in the occurrence of voids at the bonding interface when the second to fifth semiconductor chips 200a to 200d are bonded to the first semiconductor chip 100, and the second to fifth semiconductor chips 200a to 200d may be stably bonded to the first semiconductor chip 100. Accordingly, the semiconductor package 1000 may have improved durability and structural stability.

Referring to FIG. 2B, differently from a structure depicted in FIG. 2A, the semiconductor package 1000 according to some embodiments may have a structure where the second upper conductive pads UP2 and the second lower conductive pads LP2 are bonded in a misalignment manner. The second upper conductive pads UP2 may have their sidewalls spaced apart from and not in contact with sidewalls of the second lower conductive pads LP2. In other words, respective ones of the second upper conductive pads UP2 may be in contact with respective ones of the second lower conductive pads LP2, and the respective ones of the second upper conductive pads UP2 may have sidewalls that are laterally spaced apart from (e.g., in a first direction X) sidewalls of the respective ones of the second lower conductive pads LP2. Other configurations may be identical or similar to those discussed with reference to FIGS. 1 to 2A. The first direction X may be substantially parallel to the first front surface 11a of the first substrate 11.

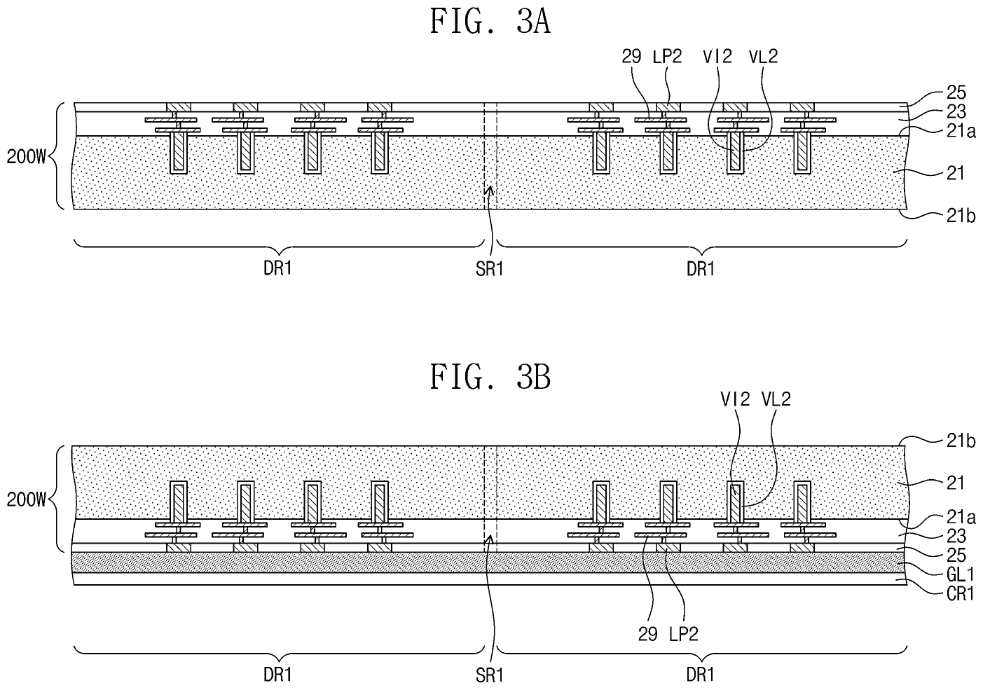

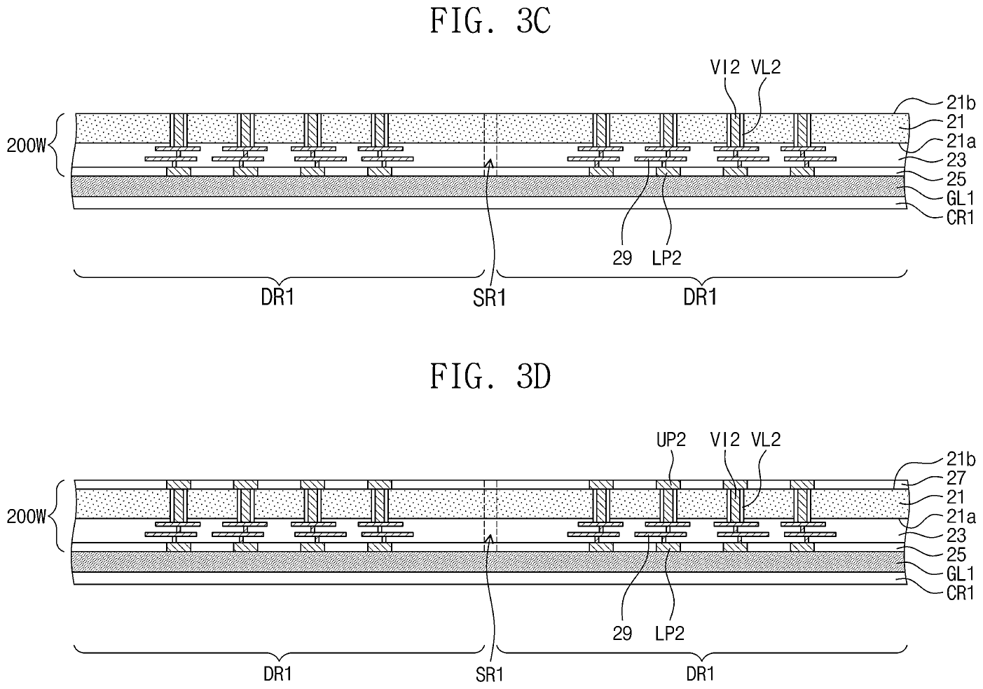

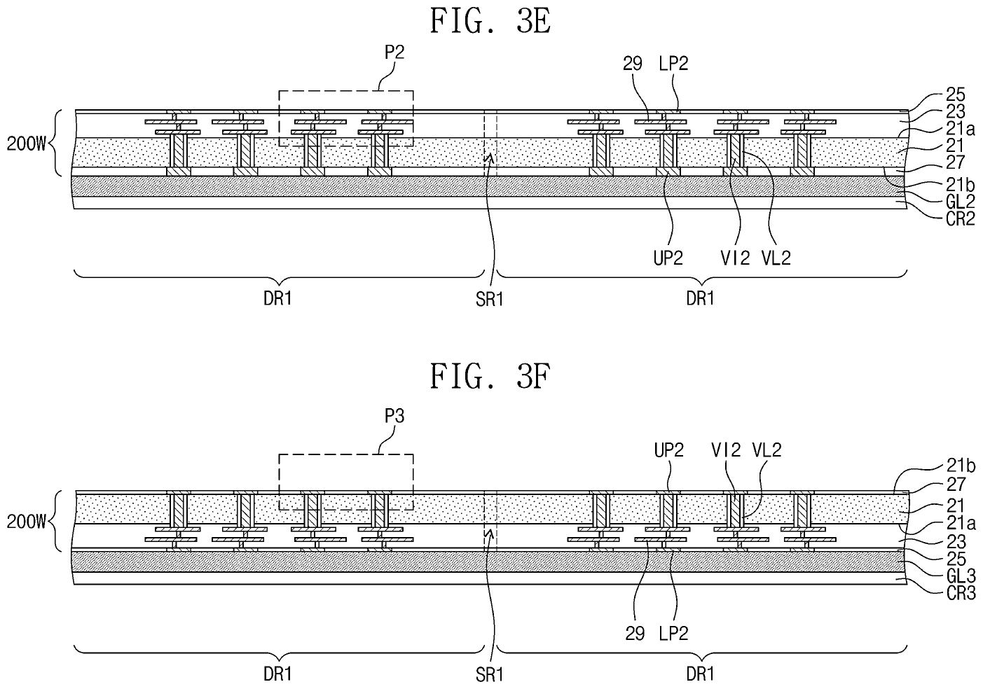

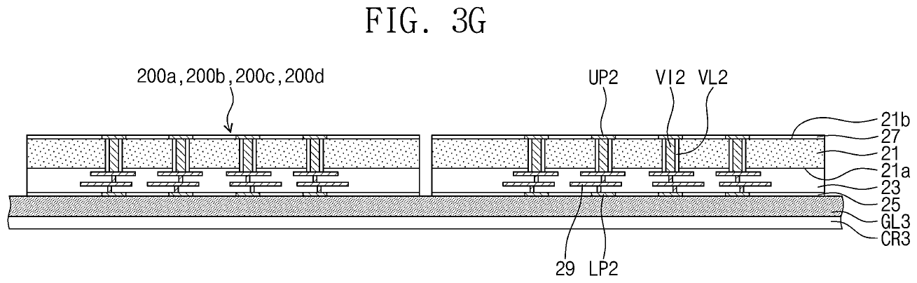

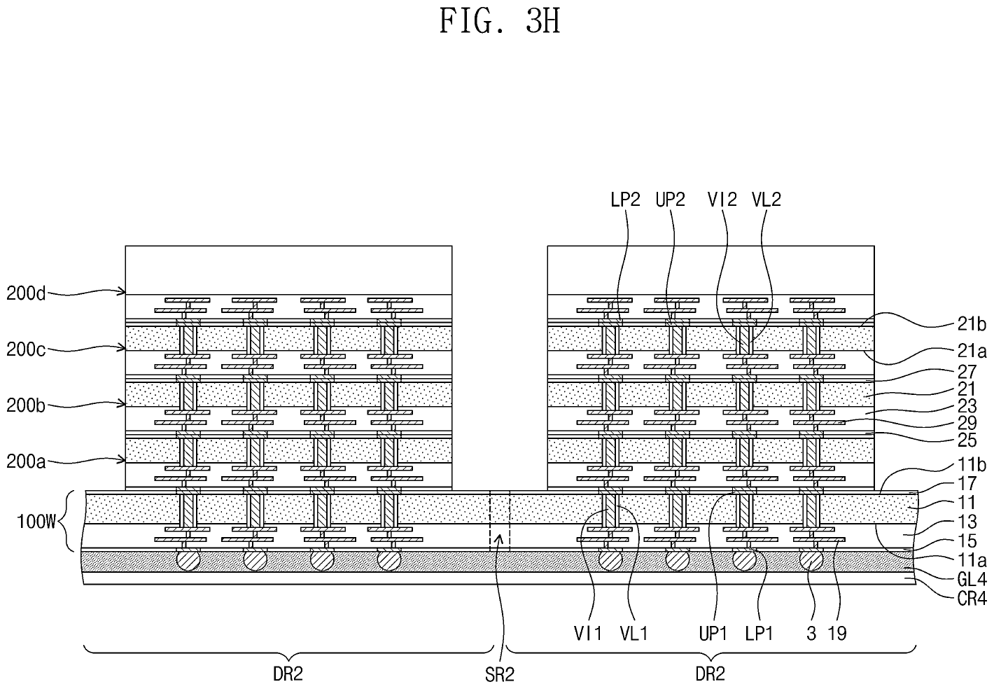

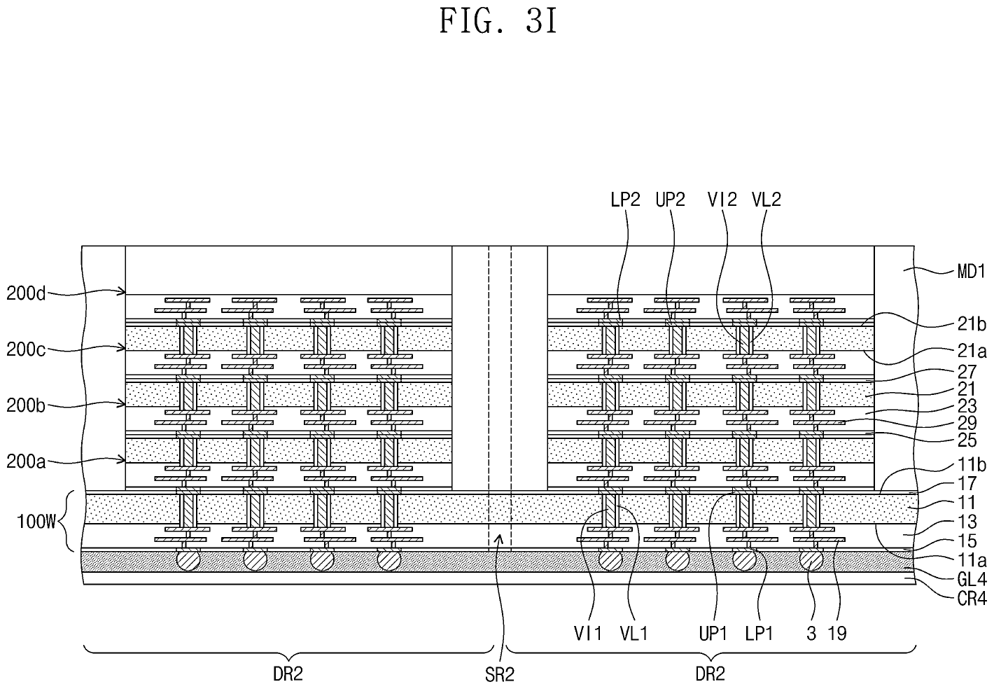

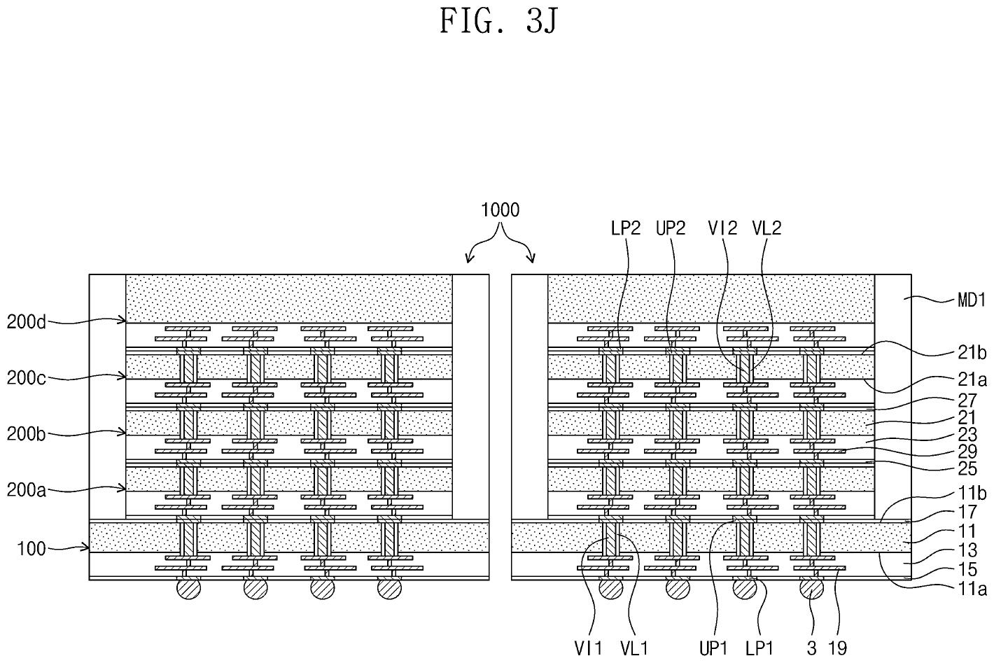

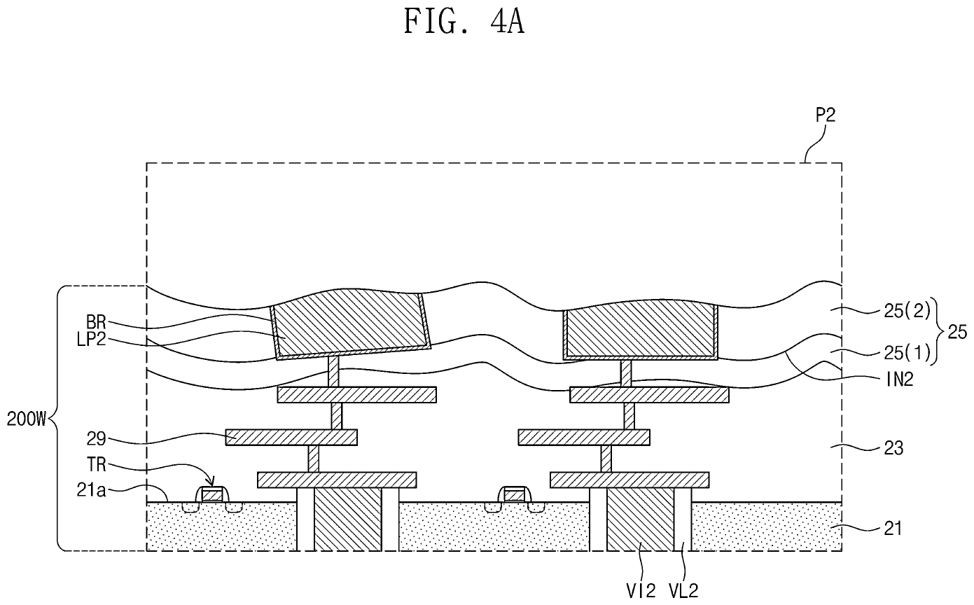

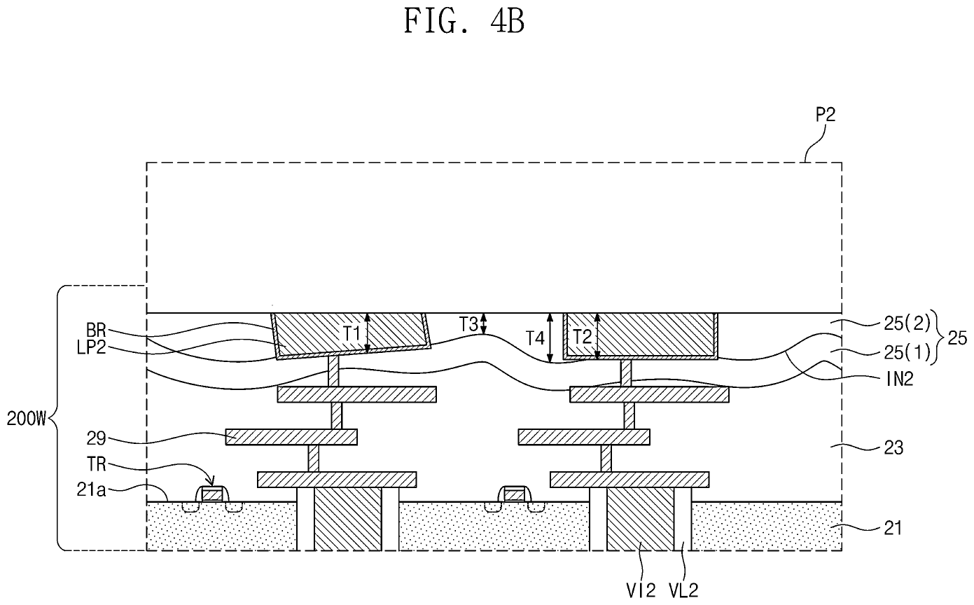

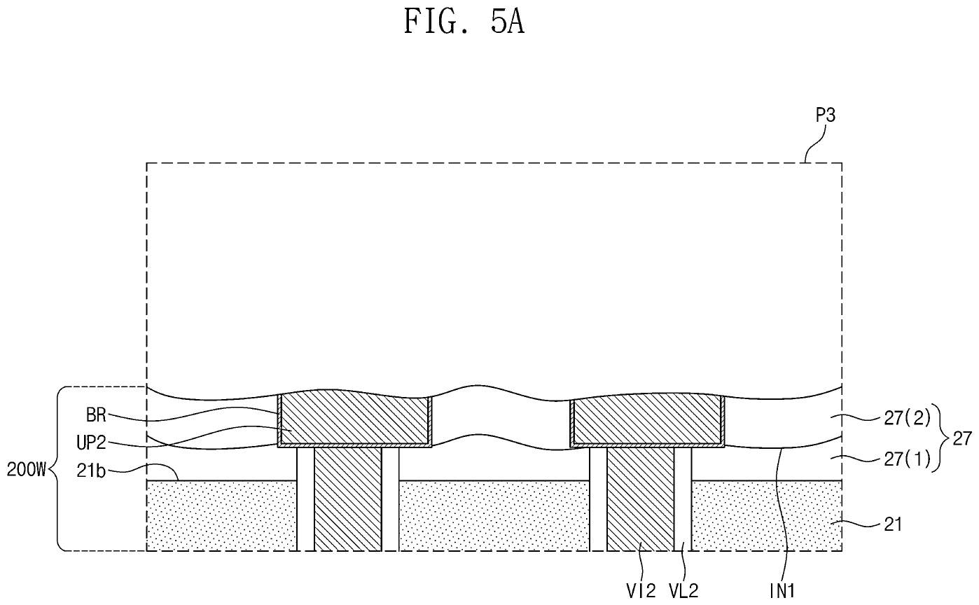

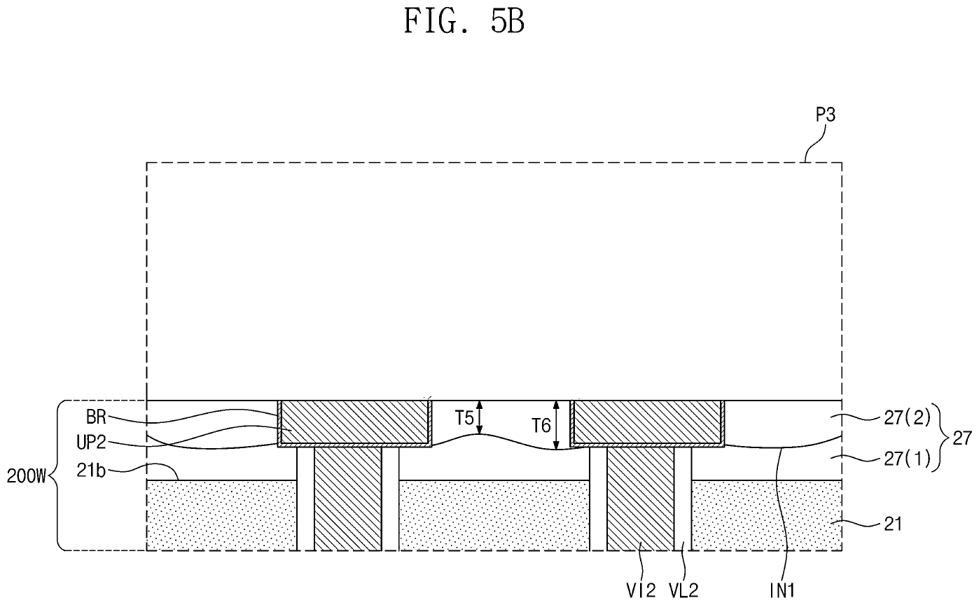

FIGS. 3A to 3J illustrate cross-sectional views showing a method of fabricating a semiconductor package depicted in FIG. 1. FIGS. 4A and 4B illustrate partially enlarged views showing section P2 of FIG. 3E. FIGS. 5A and 5B illustrate partially enlarged views showing section P3 of FIG. 3F. A duplicate description of elements described above may be omitted below for ease of description.

Referring to FIG. 3A, a second semiconductor chip wafer 200W may be prepared. The second semiconductor chip wafer 200W may have a plurality of first chip regions DR1 and a first separation region SR1 between the first chip regions DR1. The first chip regions DR1 of the second semiconductor chip wafer 200W may have structures of the second to fifth semiconductor chips 200a to 200d discussed with reference to FIGS. 1, 2A, and 2B. The first separation region SR1 may be a scribe lane region.

The second semiconductor chip wafer 200W may include a second substrate 21. Transistors (not shown), second through vias VI2, second through dielectric layers VL2, and second wiring lines 29 may be formed on the first chip regions DR1 of the second substrate 21. The second through via VI2 may not extend into (e.g., may not completely penetrate) a second rear surface 21b of the second substrate 21. A second interlayer dielectric layer 23 may be formed on a second front surface 21a of the second substrate 21, and may be on (e.g., may cover) the second wiring lines 29. Second lower conductive pads LP2 may be formed on the second interlayer dielectric layer 23, and a second lower protection layer 25 may be formed on (e.g., may cover) the second lower conductive pads LP2. Afterwards, a planarization process such as chemical mechanical polishing (CMP) may be performed to cause the second lower protection layer 25 to have a regular surface.

Referring to FIG. 3B, the second semiconductor chip wafer 200W may be bonded through a first carrier glue layer GL1 to a first carrier substrate CR1 so as to allow the second front surface 21a of the second substrate 21 to face downwards. The first carrier glue layer GL1 may include one or more of an adhesive resin, a thermosetting resin, a thermoplastic resin, and a photo-curable resin.

Referring to FIG. 3C, a grinding process may be performed to cause the second substrate 21 to have a reduced thickness. Each of at least the second substrate 21, the second through via VI2, and the second through dielectric layer VL2 may be partially removed to expose a top surface of the second through via VI2. The second through via VI2 and the second through dielectric layer VL2 may have their top surfaces coplanar with the second rear surface 21b of the second substrate 21. When grinding the second rear surface 21b of the second substrate 21, the second interlayer dielectric layer 23 and the second lower protection layer 25 may undergo undulation resulting from a difference in pressure caused by arrangement of the second wiring lines 29 and the second lower conductive pads LP2, as shown in FIG. 4A. In addition, positions of the second lower conductive pads LP2 may be inclined to cause the second lower protection layer 25 to have a curved bottom surface.

Referring to FIGS. 2A and 3D, the second rear surface 21b of the second substrate 21 may be etched back to expose an upper lateral surface of the second through dielectric layer VL2. A third upper protection layer 27(1) may be formed on the second rear surface 21b of the second substrate 21 to be on (e.g., to cover) the top surface of the second through via VI2 and the top surface of the second through dielectric layer VL2. The third upper protection layer 27(1) may undergo an etch back process or a planarization process to expose the top surface of the second through via VI2. A fourth upper protection layer 27(2) may be formed on the third upper protection layer 27(1), and then a trench may be formed to expose the second through via VI2. A barrier layer BR may be conformally formed on the fourth upper protection layer 27(2), and a plating process or a deposition process may be performed to form a conductive layer to fill the trench. A planarization process, such as chemical mechanical polishing (CMP), may be performed on the conductive layer and the barrier layer BR to form a second upper protection layer 27 and second upper conductive pads UP2. The CMP process may induce a difference in pressure resulting from arrangement of the second wiring lines 29 and the second lower conductive pads LP2, as shown in FIG. 4A, and the pressure difference may cause the second interlayer dielectric layer 23 and the second lower protection layer 25 to undergo undulation. In addition, positions of the second lower conductive pads LP2 may be inclined to cause the second lower protection layer 25 to have a curved bottom surface.

Referring to FIGS. 3E, 4A, and 4B, the second semiconductor chip wafer 200W may be bonded through a second carrier glue layer GL2 to a second carrier substrate CR2 so as to allow the second rear surface 21b of the second substrate 21 to face downwards. The second carrier glue layer GL2 may include one or more of an adhesive resin, a thermosetting resin, a thermoplastic resin, and a photo-curable resin. Afterwards, a first additional planarization process, such as CMP, may be performed to partially remove at least the second lower protection layer 25 and the second lower conductive pads LP2. Therefore, the curved surfaces of the second lower protection layer 25 and the second lower conductive pads LP2, as shown in FIG. 4A, caused by the grinding process of FIG. 3C may become planarized as illustrated in FIG. 4B. The second lower conductive pads LP2 may thus have their thicknesses that are different from each other as shown in FIG. 4B. When the first additional planarization process is performed, as shown in FIG. 5A, the second upper protection layer 27 and the second upper conductive pads UP2 may have curved surfaces.

Referring to FIGS. 3F, 5A, and 5B, the second semiconductor chip wafer 200W may be bonded through a third carrier glue layer GL3 to a third carrier substrate CR3 so as to allow the second front surface 21a of the second substrate 21 to face downwards. Afterwards, a second additional planarization process, such as CMP, may be performed to partially remove at least the second upper protection layer 27 and the second upper conductive pads UP2. Therefore, the curved surfaces of the second upper protection layer 27 and the second upper conductive pads UP2 shown in FIG. 5A may become planarized as illustrated in FIG. 5B. As discussed above, an additional planarization process may further be performed on each of the second front surface 21a and the second rear surface 21b of the second substrate 21 until the exposure of the surfaces of the second lower protection layer 25 and the second upper protection layer 27.

Referring to FIG. 3G, a dicing process may be performed such that the first separation region SR1 may be removed to form a plurality of second to fifth semiconductor chips 200a to 200d. The second to fifth semiconductor chips 200a to 200d may be separated from the third carrier glue layer GL3.

Referring to FIG. 3H, a first semiconductor chip wafer 100W may be prepared. The first semiconductor chip wafer 100W may have a plurality of second chip regions DR2 and a second separation region SR2 between the second chip regions DR2. The second chip regions DR2 of the first semiconductor chip wafer 100W may each have a structure the same as or similar to that of the first semiconductor chip 100 discussed with reference to FIG. 1. The second separation region SR2 may be a scribe lane region. The first semiconductor chip wafer 100W may include a first substrate 11.

The method as discussed above may be performed to form transistors (not shown), first through vias VI1, first through dielectric layers VL1, first wiring lines 19, a first interlayer dielectric layer 13, first upper conductive pads UP1, first lower conductive pads LP1, a first upper protection layer 17, and a first lower protection layer 15 on the second chip regions DR2 of the first substrate 11. First connection terminals 3 may be bonded to the first lower conductive pads LP1. The first semiconductor chip wafer 100W may be bonded through a fourth carrier glue layer GL4 to a fourth carrier substrate CR4 so as to cause the first connection terminals 3 to face downwards. The fourth carrier glue layer GL4 may include one or more of an adhesive resin, a thermosetting resin, a thermoplastic resin, and a photo-curable resin.

The second to fifth semiconductor chips 200a to 200d may be stacked on the second chip regions DR2 of the first semiconductor chip wafer 100W. The second semiconductor chip 200a may be disposed to allow the second front surface 21a to face the first semiconductor chip wafer 100W. The third to fifth semiconductor chips 200b to 200d may be disposed similarly in this way to sequentially stack the second to fifth semiconductor chips 200a to 200d. A thermocompression process may be performed to simultaneously bond the second to fifth semiconductor chips 200a to 200d on the first semiconductor chip wafer 100W. In this step, the first upper conductive pads UP1 and the second lower conductive pads LP2 may achieve a direct bonding between the first semiconductor chip wafer 100W and the second semiconductor chip 200a. A direct bonding may be made between the second upper conductive pads UP2 and the second lower conductive pads LP2 included in adjacent ones of the second to fifth semiconductor chips 200a to 200d.

When the second semiconductor chip 200a is bonded to the first semiconductor chip wafer 100W, because the first upper protection layer 17 of the first semiconductor chip wafer 100W has a flat top surface and the second lower protection layer 25 of the second semiconductor chip 200a has a flat top surface, there may be a reduction in the occurrence of voids at a bonding interface between the first upper protection layer 17 of the first semiconductor chip wafer 100W and the second lower protection layer 25 of the second semiconductor chip 200a. There may thus be an increase in bonding force between the first semiconductor chip wafer 100W and the second semiconductor chip 200a. As a result, a semiconductor package (see 1000 of FIG. 1) with increased durability and improved structural stability may be provided.

As discussed above, because the second upper and lower protection layers 27 and 25 of the second to fifth semiconductor chips 200a to 200d have flat surfaces as shown in FIGS. 4B and 5B, there may be a reduction in the occurrence of voids at a bonding interface between adjacent ones of the second to fifth semiconductor chips 200a to 200d. Accordingly, there may be an increase in bonding force between the second to fifth semiconductor chips 200a to 200d. As a result, a semiconductor package (see 1000 of FIG. 1) with increased durability and improved structural stability may be provided.

Referring to FIG. 3I, a molding process may be performed to form a first mold layer MD1 that is on (e.g., that covers) a top surface of the first semiconductor chip wafer 100W and lateral surfaces of the second to fifth semiconductor chips 200a to 200d.

Referring to FIG. 3J, the first semiconductor chip wafer 100W may be separated from the fourth carrier glue layer GL4, and a dicing process may be performed to remove the second separation region SR2 and to form a plurality of semiconductor packages 1000. In conclusion, the semiconductor package(s) 1000 of FIG. 1 may be fabricated.

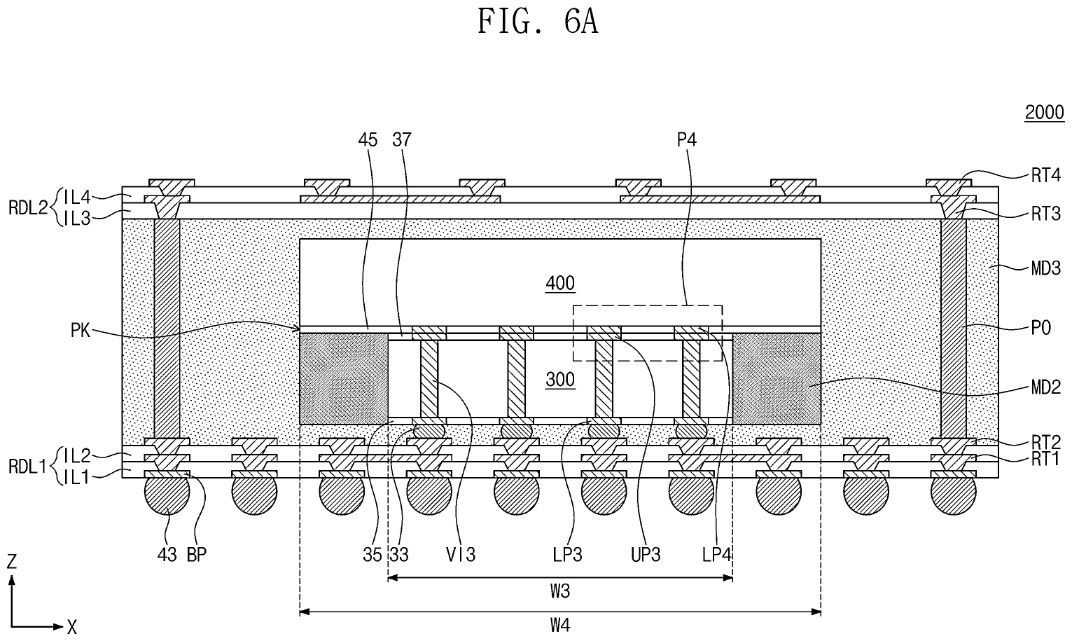

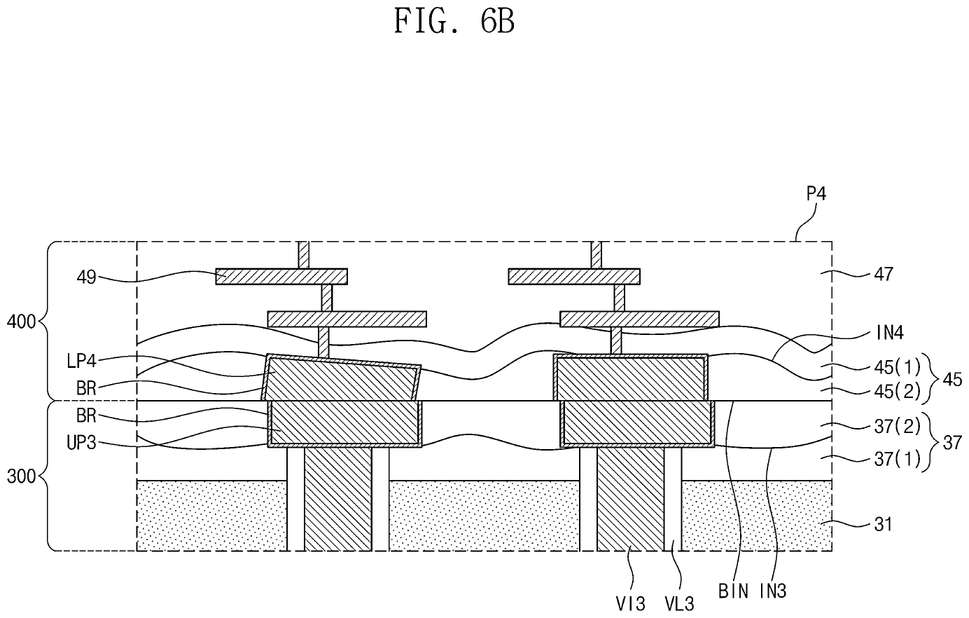

FIG. 6A illustrates a cross-sectional view showing a semiconductor package according to some embodiments of the present inventive concepts. FIG. 6B illustrates an enlarged view showing section P4 of FIG. 6A.

Referring to FIGS. 6A and 6B, a semiconductor package 2000 according to some embodiments may include a first redistribution substrate RDL1, a second redistribution substrate RDL2, a sub-semiconductor package PK, conductive pillars PO, and a third mold layer MD3. The semiconductor package 2000 may be shaped like a chip-last type fan-out wafer level package (FOWLP). Differently from that shown, in some embodiments, the semiconductor package 2000 may be shaped like a chip-first type fan-out wafer level package (FOWLP).

The sub-semiconductor package PK may be disposed on the first redistribution substrate RDL1. The sub-semiconductor package PK may be flip-chip bonded through second connection terminals 33 to the first redistribution substrate RDL1. The first redistribution substrate RDL1 and the sub-semiconductor package PK may have the third mold layer MD3 thereon. For example, the third mold layer MD3 may cover the first redistribution substrate RDL1 and the sub-semiconductor package PK. The second redistribution substrate RDL2 may be disposed on the third mold layer MD3. The conductive pillars PO may extend into (e.g., may penetrate) the third mold layer MD3 to electrically connect the first redistribution substrate RDL1 to the second redistribution substrate RDL2. The conductive pillars PO may include metal, such as copper.

The first redistribution substrate RDL1 may include first and second redistribution dielectric layers IL1 and IL2 that are sequentially stacked. The second redistribution substrate RDL2 may include third and fourth redistribution dielectric layers IL3 and IL4 that are sequentially stacked. The present inventive concepts, however, are not limited thereto, and the first and second redistribution substrates RDL1 and RDL2 may each be formed of three or more redistribution dielectric layers. Each of the first to fourth redistribution dielectric layers IL1 to IL4 may include a photo-imageable dielectric (PID) layer or an Ajinomoto build-up film (ABF).

A first redistribution pattern RT1 may be interposed between the first redistribution dielectric layer IL1 and the second redistribution dielectric layer IL2. A second redistribution pattern RT2 may be interposed between the second redistribution dielectric layer IL2 and the third mold layer MD3. A third redistribution pattern RT3 may be interposed between the third redistribution dielectric layer IL3 and the fourth redistribution dielectric layer IL4. A fourth redistribution pattern RT4 may be disposed on the fourth redistribution dielectric layer IL4. Bonding pads BP may be disposed on a bottom surface of the first redistribution dielectric layer IL1. The bonding pads BP may be in contact with the first redistribution pattern RT1. Third connection terminals 43 may be bonded to the bonding pads BP. The first to fourth redistribution patterns RT1 to RT4 and the bonding pads BP may include at least one selected from copper, aluminum, tungsten, nickel, gold, tin, and titanium. The second and third connection terminals 33 and 43 may include at least one selected from tin, lead, silver, copper, aluminum, gold, and nickel.

The sub-semiconductor package PK may include a sixth semiconductor chip 300, a seventh semiconductor chip 400 disposed on the sixth semiconductor chip 300, and a second mold layer MD2 that is on (e.g., that covers) the sixth and seventh semiconductor chips 300 and 400. The second and third mold layers MD2 and MD3 may include a dielectric resin, such as an epoxy molding compound (EMC). The sixth semiconductor chip 300 and the seventh semiconductor chip 400 may be different chips from each other. The sixth semiconductor chip 300 may have a third width W3 in a first direction X, and the seventh semiconductor chip 400 may have a fourth width W4 in the first direction X that is greater than the third width W3.

The sixth semiconductor chip 300 may include a third substrate 31 (see FIG. 6B), a third through via VI3, third wiring lines (not shown), a transistor (not shown), a third interlayer dielectric layer (not shown), third upper conductive pads UP3, third lower conductive pads LP3, a fifth upper protection layer 37, and a fifth lower protection layer 35.

The seventh semiconductor chip 400 may include a fourth substrate (not shown), fourth wiring lines 49 (see FIG. 6B), a transistor (not shown), a fourth interlayer dielectric layer 47 (see FIG. 6B), fourth upper conductive pads (not shown), fourth lower conductive pads LP4, and a sixth lower protection layer 45. In some embodiments, differently from that shown, the seventh semiconductor chip 400 may include a fourth through via (not shown).

Referring to FIG. 6B, the third upper conductive pads UP3 of the sixth semiconductor chip 300 may be in direct contact with the fourth lower conductive pads LP4 of the seventh semiconductor chip 400. The third upper conductive pads UP3 and the fourth lower conductive pads LP4 may include the same material as each other. Among the third upper conductive pads UP3 and the fourth lower conductive pads LP4, contacted ones may be merged into a single unitary object. The third upper conductive pads UP3 and the fourth lower conductive pads LP4 may have their thicknesses that are different depending on positions.

The fifth upper protection layer 37 of the sixth semiconductor chip 300 may be in contact with the sixth lower protection layer 45 of the seventh semiconductor chip 400. The fifth upper protection layer 37 may include a plurality of protection layers 37(1) and 37(2) that are sequentially stacked. The sixth lower protection layer 45 may include a plurality of protection layers 45(1) and 45(2) that are sequentially stacked. An uppermost one of the fifth upper protection layers 37(1) and 37(2) and a lowermost one of the sixth lower protection layers 45(1) and 45(2) may each have thicknesses that are different depending on position (i.e., may each have a thickness that varies). In other words, an uppermost one of the fifth upper protection layers 37(1) and 37(2) and a lowermost one of the sixth lower protection layers 45(1) and 45(2) may each have a non-uniform thickness.

A third interface IN3 between the fifth upper protection layers 37(1) and 37(2) may have a curved shape, and a fourth interface IN4 between the sixth lower protection layers 45(1) and 45(2) may have a curved shape. A bonding interface BIN having a flat shape may be provided between the fifth upper protection layer 37 and the sixth lower protection layer 45. As the bonding interface BIN is flat, there may be a reduction in the occurrence of voids between the fifth upper protection layer 37 and the sixth lower protection layer 45, and this may increase a bonding force between the sixth semiconductor chip 300 and the seventh semiconductor chip 400. Accordingly, the semiconductor package 2000 may have improved durability and structural stability. Other configurations may be identical or similar to those discussed with reference to FIGS. 1 to 2B.

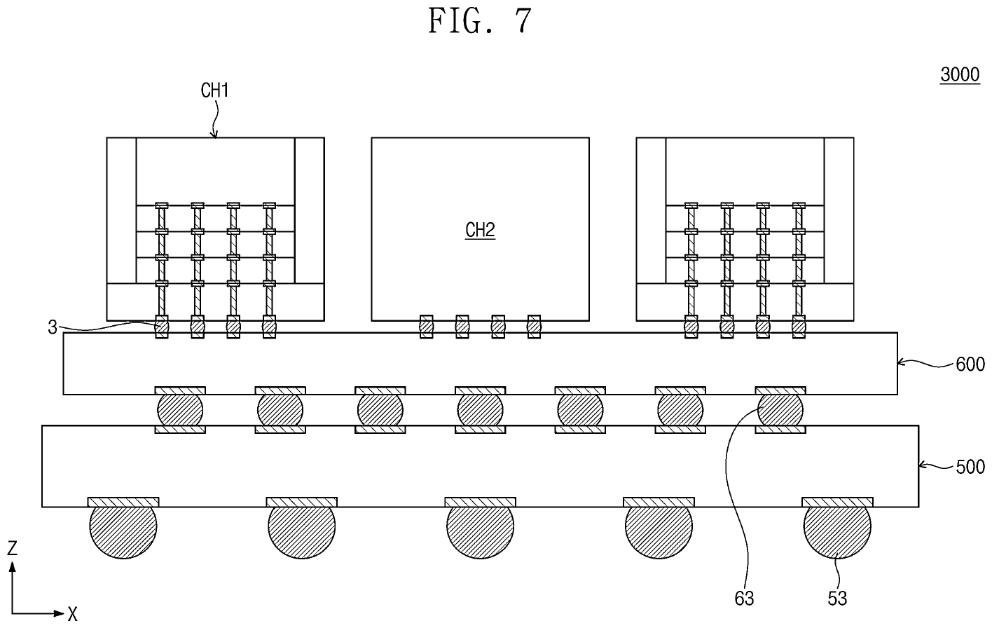

FIG. 7 illustrates a cross-sectional view showing a semiconductor package according to some embodiments of the present inventive concepts.

Referring to FIG. 7, a semiconductor package 3000 according to some embodiments may include a package substrate 500, an interposer substrate 600 disposed on the package substrate 500, first chip structures CH1 and second chip structures CH2 disposed on the interposer substrate 600. The package substrate 500 may be, for example, a double-sided or multi-layered printed circuit board (PCB). The interposer substrate 600 may include, for example, silicon. The first chip structures CH1 and the second chip structures CH2 may be disposed side by side in a first direction X on the interposer substrate 600. The interposer substrate 600 may include internal lines (not shown) that connect (e.g., electrically connect) the first chip structures CH1 to the second chip structures CH2.

The first chip structures CH1 may be connected (e.g., electrically connected) through first connection terminals 3 to the interposer substrate 600. The first chip structures CH1 may be the same as or similar to the semiconductor package 1000 discussed with reference to FIGS. 1, 2A, and 2B.

The second chip structure CH2 may be an application specific integrated circuit (ASIC) or a system-on-chip (SOC). The second chip structure CH2 may be called a host or an application processor (AP). In other embodiments, the second chip structure CH2 may be the same as or similar to the first chip structure CH1. The second chip structure CH2 may be connected (e.g., electrically connected) through first connection terminals 3 to the interposer substrate 600.

The interposer substrate 600 may be bonded through fourth connection terminals 63 to the package substrate 500. Fifth connection terminals 53 may be bonded to a bottom end of the package substrate 500. The connection terminals 3, 53, and 63 may include at least one selected from copper bumps, copper pillars, and solder balls.

In a semiconductor package according to the present inventive concepts, a semiconductor chip may undergo an additional planarization process to cause a conductive pad and a protection layer to have flat top surfaces. Thus, a flat bonding interface may be provided between semiconductor chips between which a hybrid copper (Cu) bonding or a direct bonding is provided. As the bonding interface is not curved but is instead flat, it may be possible to minimize or prevent the occurrence of voids at the bonding interface when the semiconductor chips are bonded. The reduction in the occurrence of voids at the bonding interface may induce an increase in bonding force between the semiconductor chips. As a result, the semiconductor package may have improved durability and structural stability.

Although some example embodiments of inventive concepts have been discussed with reference to accompanying figures, it will be understood that various changes in form and details may be made therein without departing from the scope of inventive concepts. It will be apparent to those skilled in the art that various substitutions, modifications, and changes may be thereto without departing from the scope of the present inventive concepts.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. In addition, it will be understood that, although the terms first, second, etc. may be used herein to describe various elements, these elements should not be limited by these terms. Rather, these terms are only used to distinguish one element from another. For example, a first element could be termed a second element, and, similarly, a second element could be termed a first element, without departing from the scope of the present disclosure.

What is claimed is:

1. A semiconductor package, comprising a plurality of semiconductor chips that are sequentially stacked,
wherein respective ones of the semiconductor chips comprise:
a substrate that has a front surface and a rear surface;
an interlayer dielectric layer on the front surface of the substrate;
a lower protection layer on a bottom surface of the interlayer dielectric layer;
a plurality of lower conductive pads in the lower protection layer;
an upper protection layer on the rear surface of the substrate; and
a plurality of upper conductive pads in the upper protection layer,
wherein the upper conductive pads of a first one of the respective ones of the semiconductor chips are respectively in contact with the lower conductive pads of an adjacent one of the respective ones of the semiconductor chips,
wherein each of the upper protection layer and the lower protection layer has a non-uniform thickness, and
wherein ones of the lower conductive pads have respective thicknesses that are different from each other.

2. The semiconductor package of claim 1, wherein the plurality of semiconductor chips include first, second, third, fourth, and fifth semiconductor chips, and
wherein a first width of the first semiconductor chip is greater than a second width of each of the second, third, fourth, and fifth semiconductor chips.

3. The semiconductor package of claim 1, wherein the respective ones of the semiconductor chips further comprise a through via.

4. The semiconductor package of claim 3, wherein a respective one of the upper conductive pads is in contact with the through via.

5. The semiconductor package of claim 1, wherein a bottom surface of the upper protection layer of the first one of the respective ones of the semiconductor chips is curved,
wherein a top surface of the lower protection layer of the adjacent one of the respective ones of the semiconductor chips is curved, and
wherein an interface between the upper protection layer of the first one of the respective ones of the semiconductor chips and the lower protection layer of the adjacent one of the respective ones of the semiconductor chips is flat.

6. The semiconductor package of claim 1, wherein the non-uniform thickness of each of the upper protection layer and the lower protection layer is in a range of about 100 angstroms (Å) to about 5,000 Å.

7. The semiconductor package of claim 1, wherein the upper conductive pads include a same material as the lower conductive pads.

8. The semiconductor package of claim 1, wherein each of the upper protection layer and the lower protection layer includes silicon oxide or silicon carbonitride.

9. The semiconductor package of claim 1, wherein a minimum thickness of the upper protection layer is in a range of about 0.1 times to about 0.9 times a maximum thickness of the upper protection layer, and
wherein a minimum thickness of the lower protection layer is in a range of about 0.1 times to about 0.9 times a maximum thickness of the lower protection layer.

10. A semiconductor package, comprising:
a first semiconductor chip; and
second to fifth semiconductor chips that are sequentially stacked on the first semiconductor chip,
wherein the first semiconductor chip comprises:
a first substrate that has a first front surface and a first rear surface opposite to each other;
a first interlayer dielectric layer on the first front surface of the first substrate;
a plurality of first lower protection layers that are stacked below the first interlayer dielectric layer;
a plurality of first lower conductive pads in a lowermost one of the first lower protection layers;
a plurality of first upper protection layers that are stacked on the first rear surface of the first substrate; and
a plurality of first upper conductive pads in an uppermost one of the first upper protection layers,
wherein respective ones of the second to fifth semiconductor chips comprise:
a second substrate that has a second front surface and a second rear surface opposite to each other;
a second interlayer dielectric layer on the second front surface of the second substrate;
a plurality of second lower protection layers that are stacked below the second interlayer dielectric layer;
a plurality of second lower conductive pads in a lowermost one of the second lower protection layers;
a plurality of second upper protection layers that are stacked on the second rear surface of the second substrate; and
a plurality of second upper conductive pads in an uppermost one of the second upper protection layers,
wherein the second upper conductive pads of a first one of the respective ones of the second to fifth semiconductor chips are respectively in contact with the second lower conductive pads of an adjacent one of the respective ones of the second to fifth semiconductor chips,
wherein the second upper conductive pads include a same material as the second lower conductive pads,
wherein the uppermost one of the second upper protection layers has a non-uniform thickness,
wherein the lowermost one of the second lower protection layers has a non-uniform thickness,
wherein a first interface between the uppermost one of the second upper protection layers and an underlying one of the second upper protection layers is curved, and
wherein a second interface between the lowermost one of the second lower protection layers and an overlying one of the second lower protection layers is curved.

11. The semiconductor package of claim 10, wherein the first upper conductive pads of the first semiconductor chip are respectively in contact with the second lower conductive pads of the second semiconductor chip, and
wherein the first upper conductive pads of the first semiconductor chip include a same material as the second lower conductive pads of the second semiconductor chip.

12. The semiconductor package of claim 10, wherein the first semiconductor chip further comprises a first through via,
wherein the respective ones of the second to fifth semiconductor chips further comprise a second through via,
wherein a respective one of the first upper conductive pads is in contact with the first through via, and
wherein a respective one of the second upper conductive pads is in contact with the second through via.

13. The semiconductor package of claim 10, wherein each of the uppermost one of the first upper protection layers and the uppermost one of the second upper protection layers has a thickness in a range of about 100 angstroms (Å) to about 5,000 Å, and
wherein each of the lowermost one of the first lower protection layers and the lowermost one of the second lower protection layers has a thickness in a range of about 100 Å to about 5,000 Å.

14. The semiconductor package of claim 10, wherein ones of the second lower conductive pads have respective thicknesses that are different from each other.

15. The semiconductor package of claim 10, wherein the uppermost one of the first upper protection layers, the uppermost one of the second upper protection layers, the lowermost one of the first lower protection layers, and the lowermost one of the second lower protection layers include silicon oxide or silicon carbonitride.

16. The semiconductor package of claim 10, wherein a minimum thickness of the uppermost one of the second upper protection layers is in a range of about 0.1 times to about 0.9 times a maximum thickness of the uppermost one of the second upper protection layers, and
wherein a minimum thickness of the lowermost one of the second lower protection layers is in a range of about 0.1 times to about 0.9 times a maximum thickness of the lowermost one of the second lower protection layers.

17. A semiconductor package, comprising:
a package substrate;
an interposer substrate on the package substrate;
a plurality of first chip structures on the interposer substrate; and
a second chip structure on the interposer substrate,
wherein each of the plurality of first chip structures includes a plurality of semiconductor chips that are sequentially stacked,
wherein respective ones of the semiconductor chips comprise:
a substrate that has a front surface and a rear surface;
an interlayer dielectric layer on the front surface of the substrate;
a lower protection layer on a bottom surface of the interlayer dielectric layer;
a plurality of lower conductive pads in the lower protection layer;
an upper protection layer on the rear surface of the substrate; and
a plurality of upper conductive pads in the upper protection layer,
wherein the upper conductive pads of a first one of the respective ones of the semiconductor chips are respectively in contact with the lower conductive pads of an adjacent one of the respective ones of the semiconductor chips,
wherein each of the upper protection layer and the lower protection layer has a non-uniform thicknesses, and
wherein the non-uniform thickness of each of the upper protection layer and the lower protection layer is in a range of about 100 angstroms (Å) to about 5,000 Å.

18. The semiconductor package of claim 17, wherein a bottom surface of the upper protection layer of the first one of the respective ones of the semiconductor chips and a top surface of the lower protection layer of the adjacent one of the respective ones of the semiconductor chips are both curved, and
wherein an interface between the upper protection layer of the first one of the respective ones of the semiconductor chips and the lower protection layer of the adjacent one of the respective ones of the semiconductor chips is flat.

19. The semiconductor package of claim 17, wherein ones of the lower conductive pads have respective thicknesses that are different from each other.

20. The semiconductor package of claim 17, wherein a minimum thickness of the upper protection layer is in a range of about 0.1 times to about 0.9 times a maximum thickness of the upper protection layer, and
wherein a minimum thickness of the lower protection layer is in a range of about 0.1 times to about 0.9 times a maximum thickness of the lower protection layer.
